(19) United States
(12) Patent Application Publication
(10) Pub. No.: US 2026/0150698 A1
(43) Pub. Date: May 28, 2026

(54) SEMICONDUCTOR DEVICE, POWER SUPPLY DEVICE, AND VEHICLE

(71) Applicant: ROHM CO., LTD., Kyoto (JP)

(72) Inventors: Isamu IWAHASHI, Kyoto (JP); Naotaro HIRADE, Kyoto (JP)

(21) Appl. No.: 19/456,221

(22) Filed: Jan. 22, 2026

Related U.S. Application Data
(63) Continuation of application No. PCT/JP2024/025095, filed on Jul. 11, 2024.

(30) Foreign Application Priority Data
Jul. 24, 2023 (JP) 2023-120006

(51) Int. Cl. H10W 42/20; H10W 20/40; H10W 20/41

(52) U.S. Cl. CPC H10W 42/267; H10W 20/423; H10W 20/496

(57) ABSTRACT

A pattern (2, 2A, 2B, 2C) of a semiconductor device (100, 100A, 100B, 100C) includes a first node (21, 21a, 21b, 21c) formed in an outer circumferential portion and configured to be connected to a first potential and a second node (22, 22b, 22c) insulated from the first node (21, 21a, 21b, 21c) and configured to receive application of a second potential different from the first potential. The first node (21, 21a, 21b, 21c) and the second node (22, 22b, 22c) are configured to be at least partly opposed to each other.

### CROSS-REFERENCE TO RELATED APPLICATIONS

This nonprovisional application is a continuation application of International Patent Application No. PCT/JP 2024/025095 filed on Jul. 11, 2024, which claims priority to Japanese Patent Application No. 2023-120006 filed on Jul. 24, 2023, the entire contents of which are hereby incorporated by reference.

### TECHNICAL FIELD

The present disclosure relates to a semiconductor device and relates also to a power supply device and a vehicle that use the semiconductor device.

### BACKGROUND ART

In a semiconductor device, radiation noise or emission noise may be generated by, for example, switching of a switching element. These types of noise are referred to also as EMI (electromagnetic interference).

When a level of EMI radiated by the semiconductor device is high, other electronic apparatuses might be adversely affected, and thus a regulation value for this purpose is set for electronic apparatuses. Further, there is known an electronic apparatus including an electronic component for EMI prevention housed in a package of a semiconductor device (see, for example, Patent Document 1).

### CITATION LIST

### Patent Literature

Patent Document 1: Japanese Unexamined Patent Application Publication No. 2018-14793

### BRIEF DESCRIPTION OF DRAWINGS

FIG. 1 is a schematic layout diagram of a semiconductor device.

FIG. 2 is an enlarged sectional view of a pattern of the semiconductor device.

FIG. 3 is an equivalent circuit diagram of the semiconductor device.

FIG. 4 is a schematic layout diagram of a semiconductor device according to a first modification example.

FIG. 5 is an equivalent circuit diagram of the semiconductor device shown in FIG. 4.

FIG. 6 is a schematic layout diagram of a semiconductor device according to a second modification example.

FIG. 7 is a schematic sectional view of a semiconductor device according to a third modification example.

FIG. 8 is a view showing an outer appearance of a vehicle.

### DESCRIPTION OF EMBODIMENTS

In the present description, a MOS (metal oxide semiconductor) field effect transistor refers to a transistor whose gate structure is composed of at least three layers of a “layer formed of a conductor or a semiconductor having a low resistance value such as polysilicon,” an “insulating layer,” and a “P-channel type, N-channel type, or intrinsic semiconductor layer”. That is, the gate structure of the MOS field effect transistor is not limited to a three-layer structure of a metal, an oxide, and a semiconductor.

The following describes an embodiment of the present disclosure with reference to the appended drawings. The present description assumes that a state where members are connected to each other encompasses not only their mechanically connected state but also their electrically connected state, i.e., a state where current flows therebetween. The term “to connect,” therefore, encompasses a case of “establishing electrical connection.”

### Semiconductor Device 100

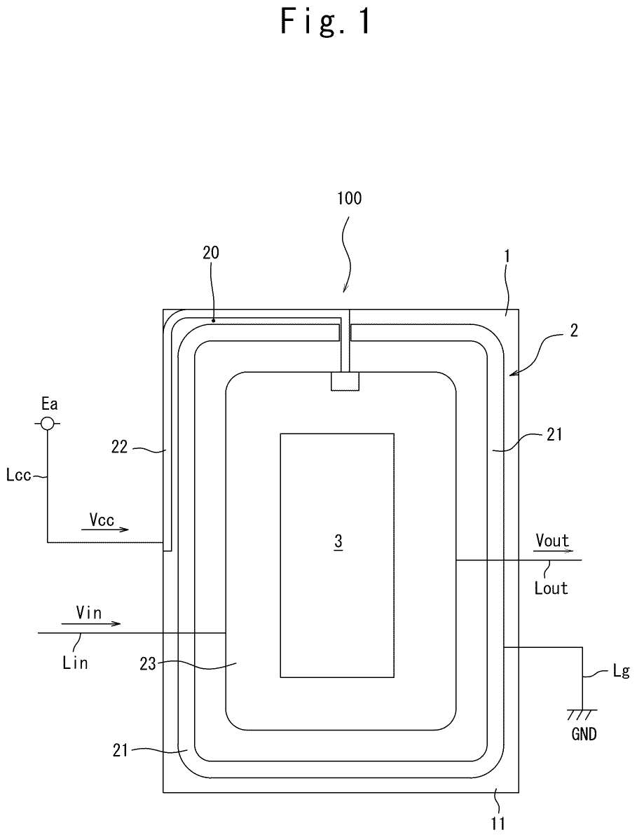

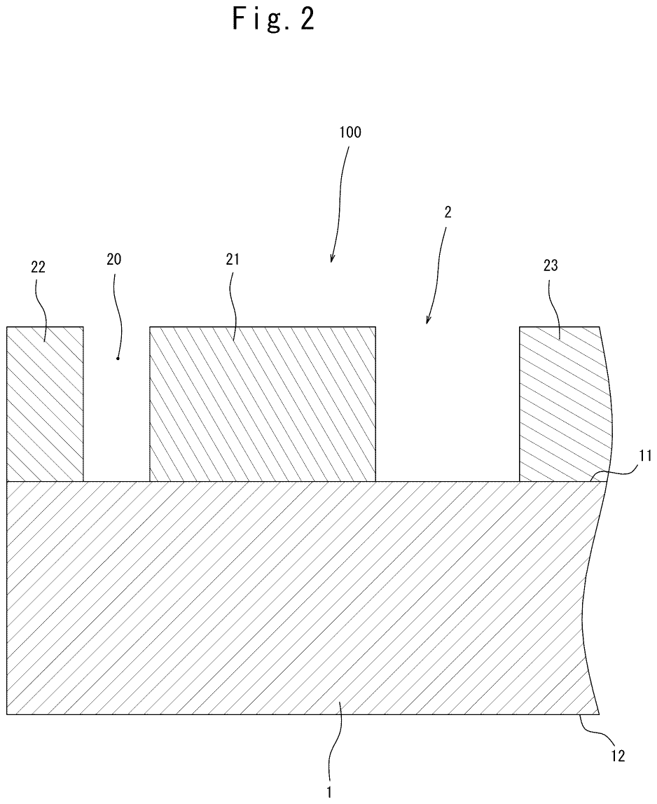

FIG. 1 is a schematic layout diagram of a semiconductor device 100. FIG. 2 is an enlarged sectional view of a pattern 2 of the semiconductor device 100. The semiconductor device 100 is used as a power supply device. The semiconductor device 100 includes a substrate 1, the pattern 2, and a plurality of electronic components 3. Further, the semiconductor device 100 is housed in a single package. Being housed in a package refers to being regarded as one component when viewed externally and may encompass a case of being molded of a resin and housed in a metal or resin casing. There is no particular limitation on a mode of the package.

The electronic components 3, upon a voltage being applied thereto, execute preset operations. Examples of the plurality of electronic components 3 include a power MOS transistor, an IGBT (insulated gate bipolar transistor), an inverter, and a controller. The semiconductor device 100 is used herein as a power supply device. The electronic components 3 included in the semiconductor device 100 can form circuitry capable of outputting an output voltage Vout obtained by stepping up or stepping down an input voltage Vin. Furthermore, a functional IC (integrated circuit) capable of executing a predetermined function may be formed by combining the above-described electronic components and adopted as the electronic components 3.

As shown in FIG. 2, the substrate 1 is in a plate shape rectangular in a planar view and has each end face in a thickness direction thereof as a component mounting surface. This embodiment is described assuming that the thickness direction of the substrate 1 corresponds to a top-bottom direction, namely, a gravity acting direction, in which upper and lower surfaces of the substrate 1 are denoted 11 and 12, respectively. The upper surface 11 and the lower surface 12 described herein are not intended to limit a direction in a used state of the semiconductor device 100. The pattern 2 is formed on each of the upper surface 11 and the lower surface 12 of the substrate 1.

The pattern 2 is, for example, a patterned wiring formed on a surface of the substrate 1. The description herein assumes that the pattern 2 is configured to be formed on the upper surface 11 of the substrate 1. The pattern 2 may be formed on each of both the surfaces of the substrate 1 or on each layer of the substrate 1 when formed of a multilayer substrate.

Furthermore, in the planar view, the pattern 2 includes a first node 21, a second node 22, and a third node 23. In the planar view, the first node 21 is formed along an outer circumferential portion. The first node 21 is connected to a ground potential GND that is a first potential.

In the planar view, the second node 22 is formed on an outer side relative to the first node 21 in the outer circumferential portion of the substrate 1. The second node 22 is connected to a second potential Ea different from the first potential. The second potential Ea is such a potential that a control voltage Vcc for operating the electronic components 3 can be supplied and is one example of a power supply potential. To be more specific, it can be said that, when the electronic components 3 operate using the ground potential GND as a reference potential, the second potential Ea is higher than the ground potential GND by not less than a value of the control voltage Vcc.

In the planar view, the third node 23 is arranged on an inner side with respect to the first node 21 on the substrate 1. The third node 23 establishes connection among the plurality of electronic components 3 so that circuitry is formed. That is, by the third node 23, the electronic components 3 are connected to form circuitry that executes a predetermined operation in the semiconductor device 100. The third node 23 is configured to have a portion connectable to both the first node 21 and the second node 22.

In the semiconductor device 100, the first node 21 connected to the ground potential GND is arranged on an outer side with respect to the circuitry formed by connecting the electronic components 3 to the third node 23. This allows a high voltage resulting from external ESD (electrostatic discharge) to flow through the first node 21 to the ground potential GND. Thus, even when ESD occurs to the semiconductor device 100, it is possible to suppress application of such a high voltage to the internal circuitry formed of the third node 23 and an electronic apparatus.

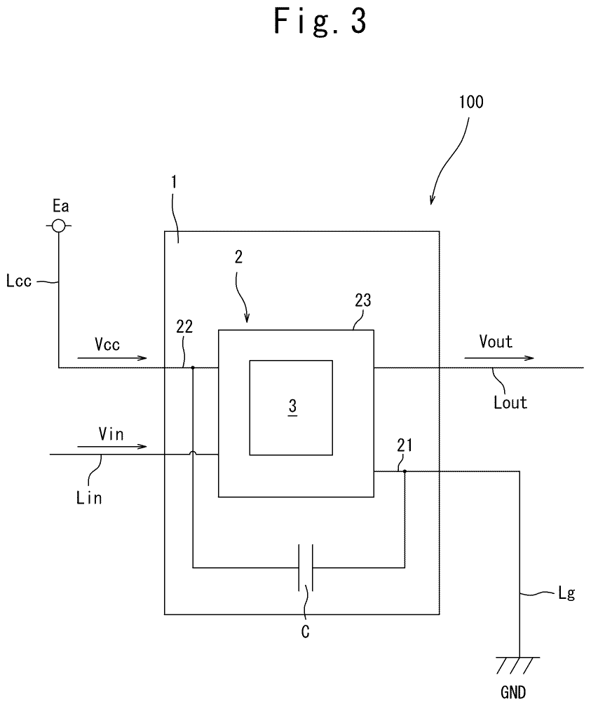

As shown in FIG. 2, the second node 22 and the first node 21 are opposed to each other via a gap 20 in a direction along the upper surface 11 of the substrate 1. The second node 22 is arranged on an outer side with respect to the first node 21. Thus, the first node 21 and the second node 22 constitute a capacitor C (see FIG. 3 referred to later). The gap 20 may be a space, or a member having a high dielectric constant may be arranged in the gap 20. For example, in a case of performing resin molding to form the package, a resin used to form the package is filled in the gap 20.

FIG. 3 is an equivalent circuit diagram of the semiconductor device 100. In the circuit diagram shown in FIG. 3, the first node 21 constitutes a part of a ground line Lg and is connected to the ground potential GND. Furthermore, the second node 22 constitutes a part of a control power supply line Lcc and is connected to the second potential Ea for supplying the control voltage Vcc to the electronic components 3. Further, the control power supply line Lcc is connected to the ground line Lg via the capacitor C. That is, the control power supply line Lcc is connected to the ground potential GND via the capacitor C. Furthermore, the electronic components 3 are provided with an input line Lin through which the input voltage Vin is inputted and an output line Lout through which the output voltage Vout is outputted. The semiconductor device 100 outputs the output voltage Vout obtained by stepping up or stepping down the input voltage Vin inputted through the input line Lin.

The second node 22 as the part of the control power supply line Lcc is indirectly or directly connected to the electronic components 3 via the third node 23. Thus, the control voltage Vcc is applied to the electronic components 3 connected thereto. Furthermore, the control power supply line Lcc is connected to the ground potential GND via the capacitor C. Thus, the capacitor C functions as a noise filter. For example, via the second node 22, EMI (electromagnetic interference) noise may be superimposed on the control voltage Vcc and inputted in that state to the semiconductor device 100. Even in such a case, the noise is eliminated by the capacitor C. Thus, it is possible to suppress an influence of noise on the circuitry inside the semiconductor device 100.

That is, in the semiconductor device 100, the first node 21 and the second node 22 of the pattern 2 can constitute the capacitor C. This allows an influence of noise from outside the semiconductor device 100 to be reduced without requiring that a noise elimination capacitor be separately provided outside the circuitry.

While this embodiment exemplarily describes a configuration in which the first node 21 is connected to the ground potential GND, there is no limitation thereto. The first node 21 may be connected to a reference potential for the electronic components 3 in the semiconductor device 100. The reference potential is a potential lower than the second potential Ea. With this configuration, the capacitor C is formed between the first node 21 and the second node 22, and thus it is possible to eliminate noise inputted via the second node 22.

Furthermore, while the second node 22 is configured to be connected to the second potential Ea, there is no limitation thereto. It is possible to widely adopt a configuration in which the second node 22 is connected to such a potential that a signal (or a voltage) on which noise is likely to be superimposed is inputted or outputted, which is different from a potential at the first node 21. Examples of such a line include lines through which an output voltage, a reset signal, and so on are inputted/outputted. Furthermore, the second node 22 may also be configured to form a line other than these.

In any case, noise inputted to the second node 22 or outputted from the second node 22 is eliminated by the capacitor C constituted of the first node 21 and the second node 22. As described above, the first node 21 and the second node 22 of the pattern 2 arranged on the substrate 1 constitute the capacitor C for eliminating noise, and thus compared with a case where a component for EMI prevention is mounted, it is possible to achieve miniaturization of the package of the semiconductor device 100.

### First Modification Example

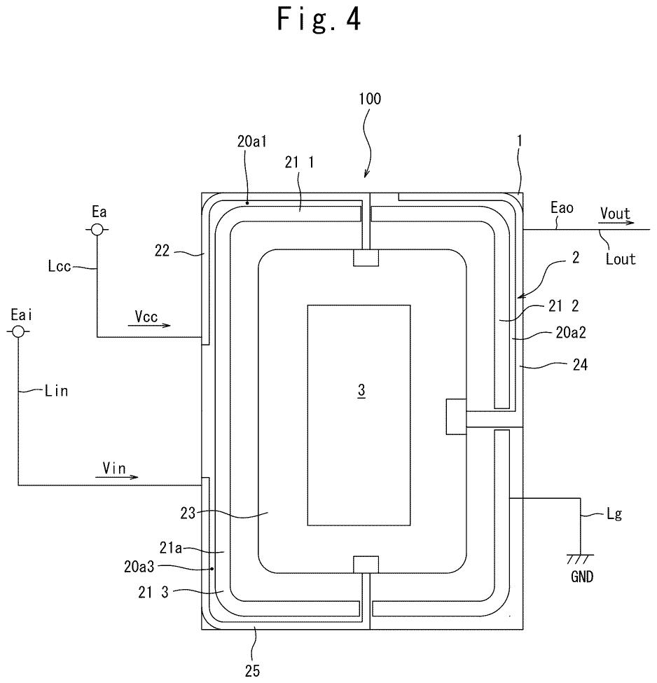

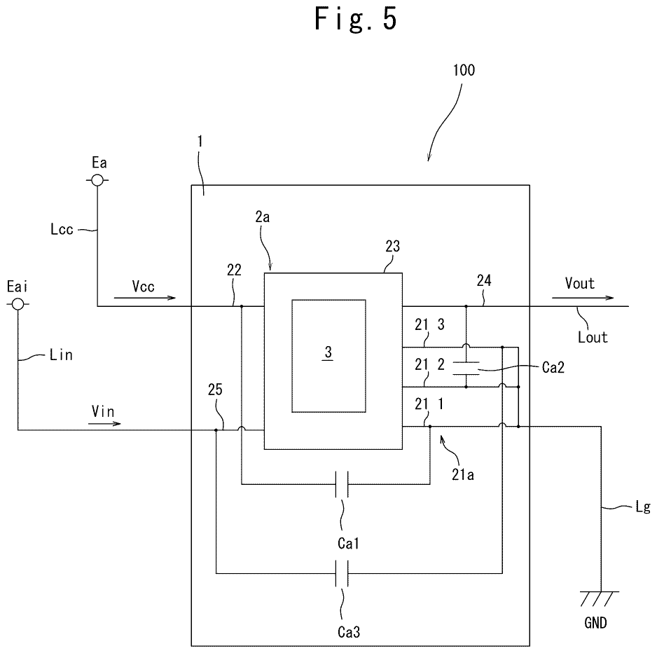

FIG. 4 is a schematic layout diagram of a semiconductor device 100A according to a first modification example. FIG. 5 is an equivalent circuit diagram of the semiconductor device 100A shown in FIG. 4. In the semiconductor device 100A shown in FIG. 4, for the sake of description, a first node 21 a is divided into a first region 21r1, a second region 21r2, and a third region 21r3. Furthermore, a difference from the semiconductor device 100 is that a pattern 2A includes a fourth node 24 and a fifth node 25 in addition to a second node 22. Other than these, the semiconductor device 100A is the same in configuration as the semiconductor device 100.

Portions of the semiconductor device 100A substantially the same as those of the semiconductor device 100 are, therefore, denoted by the same reference characters, and detailed descriptions thereof are omitted. The second node 22, the fourth node 24, and the fifth node 25 are the same in configuration and different only in that they are connected to different potentials. This renders the second node 22, the fourth node 24, and the fifth node 25 interchangeable among themselves. In other words, it can be said that the fourth node 24 and the fifth node 25 are each another example of the second node 22.

In the first node 21a, the first region 21r1, the second region 21r2, and the third region 21r3 are integrally formed, and the first node 21a is connected to a ground potential GND. That is, the first region 21r1, the second region 21r2, and the third region 21r3 are all at the ground potential GND. Further, in a planar view, the second node 22 is arranged on an outer side with respect to the first region 21r1 so as to face the first region 21r1 via a gap 20a1. Similarly, in the planar view, the fourth node 24 is arranged on an outer side with respect to the second region 21r2 so as to face the second region 21r2 via a gap 20a2. Moreover, in the planar view, the fifth node 25 is arranged on an outer side with respect to the third region 21r3 so as to face the third region 21r3 via a gap 20a3.

As shown in FIG. 4, the second node 22 is connected to a second potential Ea and constitutes a part of a control power supply line Lcc. Furthermore, the fourth node 24 is connected to a terminal of electronic components 3 from which an output voltage Vout is outputted and constitutes a part of an output line Lout. The output voltage Vout is a voltage to be supplied by the semiconductor device 100A to an external apparatus. An output potential Eao on the output line Lout including the fourth node 24 is, therefore, higher than the ground potential GND.

The fifth node 25 is connected to a power supply potential Eai and constitutes a part of an input line Lin through which an input voltage Vin is inputted to the electronic components 3. The electronic components 3 step up or step down the input voltage Vin and outputs the resulting output voltage Vout. The electronic components 3 operate using the ground potential GND as a reference potential, and the power supply potential Eai is higher than the ground potential GND.

As described above, the second node 22 and the first region 21r1 of the first node 21a opposed to each other via the gap 20a1 are at different potentials. The second node 22 and the first region 21r1 of the first node 21a, therefore, form a capacitor Ca1 as shown in FIG. 5. Furthermore, the fourth node 24 and the second region 21r2 of the first node 21a opposed to each other via the gap 20a2 form a capacitor Ca2. Moreover, the fifth node 25 and the third region 21r3 of the first node 21a opposed to each other via the gap 20a3 form a capacitor Ca3.

The capacitor Ca1 composed of the second node 22 and the first region 21rl of the first node 21 operates as a noise filter. The capacitor Ca1 eliminates noise inputted together with a control voltage Vcc supplied via the second node 22.

Furthermore, the capacitor Ca2 composed of the fourth node 24 and the second region 21r2 of the first node 21 operates as a smoothing capacitor. The semiconductor device 100A may include, for example, an electronic component 3 forming a step-up circuit or a step-down circuit that uses a switching element to convert the input voltage Vin into the output voltage Vout. The switching element is an element that performs voltage conversion by being switched at a high speed and might generate noise (switching noise) during a switching operation. The switching noise, though disadvantageously contained in the output voltage Vout, is eliminated by the capacitor Ca2. That is, it is possible to suppress a phenomenon in which an influence of noise generated inside the semiconductor device 100A is exerted outside the semiconductor device 100A.

Moreover, the capacitor Ca3 composed of the fifth node 25 and the third region 21r3 of the first node 21 operates as a noise filter. The input voltage Vin is supplied from the power supply potential Eai to the semiconductor device 100A. At this time, noise may be contained in the input voltage Vin. The capacitor Ca3 operates as the noise filter to eliminate the noise contained in the input voltage Vin. Thus, the input voltage Vin from which the noise has been eliminated is inputted, so that an influence of the noise externally contained in the input voltage Vin is eliminated.

As in the semiconductor device 100A described above, each line through which an input or an output (a voltage, a signal) flows may be arranged so that a gap is provided from a corresponding one of a plurality of regions into which the first node 21 connected to the ground potential GND is divided, i.e., so as to form a capacitor. With this configuration, compared with a case where a capacitor for eliminating noise is provided on each line, it is possible to achieve miniaturization of the semiconductor device 100A.

As potentials to which the second node 22, the fourth node 24, and the fifth node 25 forming the capacitors are connected, other than a configuration in which they are connected to the above-described potentials, any potential can be widely adopted as long as the potential is such that a signal or a voltage on which noise is likely to be superimposed is inputted or outputted.

### Second Modification Example

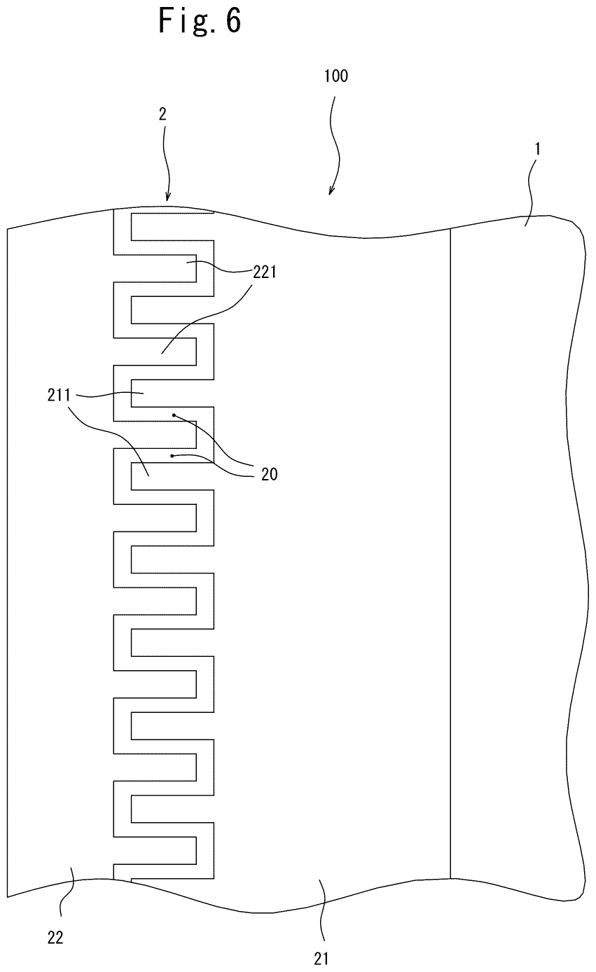

FIG. 6 is an enlarged layout diagram of a semiconductor device 100B according to a second modification example. FIG. 6 shows an enlarged view of an area where a first node 21b and a second node 22b of a pattern 2B of the semiconductor device 100B are opposed to each other. In the semiconductor device 100B shown in FIG. 6, the area where the first node 21b and the second node 22b of the pattern 2B are opposed to each other has a shape different from that in the semiconductor device 100. Other than this, the semiconductor device 100B is substantially the same in configuration as the semiconductor device 100, and portions thereof substantially the same as those of the semiconductor device 100 are denoted by the same reference characters, with detailed descriptions thereof omitted.

As shown in FIG. 6, the first node 21b includes a plurality of outwardly protruding first protrusions 211. The first protrusions 211 are arrayed at intervals in a direction intersecting a protruding direction thereof. Furthermore, the second node 22b arranged on an outer side with respect to the first node 21b includes a plurality of inwardly protruding second protrusions 221.

Further, as shown in FIG. 6, the first protrusions 211 and the second protrusions 221 are arranged alternately side by side with a gap 20b provided therebetween. When thus arranged alternately, the first protrusions 211 and the second protrusions 221 constitute a capacitor. The first protrusions 211 and the second protrusions 221 are configured in this manner, and thus the area where the first node 21b and the second node 22b are opposed to each other is increased. That is, it is possible to increase an electrostatic capacitance of the capacitor constituted of the first node 21b and the second node 22b. This allows a larger amount of noise to be eliminated.

### Third Modification Example

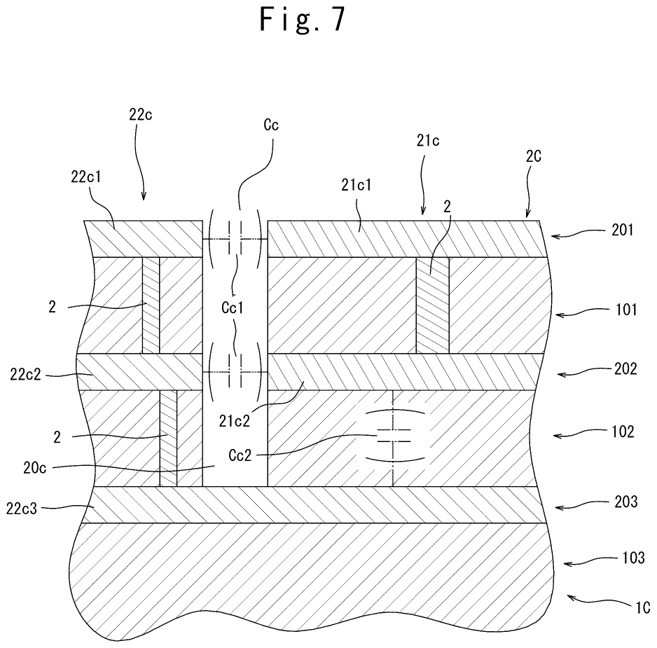

FIG. 7 is a schematic sectional view of a semiconductor device 100C according to a third modification example. In the semiconductor device 100C shown in FIG. 7, a substrate 1C is a multilayer substrate, and a pattern is formed on each layer thereof. Other than this, the semiconductor device 100C is the same in configuration as the semiconductor device 100. Portions of the semiconductor device 100C substantially the same as those of the semiconductor device 100 are, therefore, denoted by the same reference characters, and detailed descriptions thereof are omitted.

As shown in FIG. 7, in the semiconductor device 100C, the substrate 1C is a multilayer substrate. The substrate 1C is composed of a first layer 101, a second layer 102, and a third layer 103 stacked in this order from the top. Furthermore, a pattern 2C includes a first pattern 201 formed on the first layer 101, a second pattern 202 formed on the second layer 102, and a third pattern 203 formed on the third layer 103. The first pattern 201 is formed on an upper surface of the first layer 101, the second pattern 202 is formed on an upper surface of the second layer 102, and the third pattern 203 is formed on an upper surface of the third layer 103.

A first node 21c is configured to include a first layer portion 21c1 formed in the first pattern 201 and a second layer portion 21c2 formed in the second pattern 202. A connection between the first layer portion 21c1 and the second layer portion 21c2 of the first node 21c is established by a via 26.

A second node 22c is configured to include a first layer portion 22c1 formed in the first pattern 201, a second layer portion 22c2 formed in the second pattern 202, and a third layer portion 22c3 formed in the third pattern 203. A connection between the first layer portion 22c1 and the second layer portion 22c2 of the second node 22c and a connection between the second layer portion 22c2 and the third layer portion 22c3 thereof are established by vias 26.

Further, the first layer portion 21c1 and the second layer portion 21c2 of the first node 21c are opposed to the first layer portion 22c1 and the second layer portion 22c2 of the second node 22c, respectively, via a gap 20c in a direction orthogonal to a stacking direction of the substrate 1C (a top-bottom direction). Thus, each of the first layer portion 21c1 and the second layer portion 21c2 of the first node 21c and a corresponding one of the first layer portion 22c1 and the second layer portion 22c2 of the second node 22c constitutes a capacitor Cc1 (shown by a chain double-dashed line in FIG. 7).

Furthermore, the third layer portion 22c3 of the second node 22c extends below the second layer portion 21c2 of the first node 21c. Thus, the third layer portion 22c3 of the second node 22c and the second layer portion 21c2 of the first node 21c are arranged side by side in the stacking direction of the substrate 1C (the top-bottom direction) via the second layer 102 of the substrate 1C. Thus, the second layer portion 21c2 of the first node 21c and the third layer portion 22c3 of the second node 22c constitute a capacitor Cc2 (shown by a chain double-dashed line in FIG. 7).

Further, the first node 21c and the second node 22c constitute a capacitor Cc having a capacitance obtained by connecting the capacitors Cc1 and the capacitor Cc2 in parallel. That is, the use of the multilayer substrate 1C allows the first node 21c and the second node 22c to be placed in line in the stacking direction of the substrate 1C, and thus it is possible to increase the capacitance of the capacitor Cc constituted of the first node 21c and the second node 22c.

While this modification example is configured to have both an area where the first node 21c and the second node 22c are opposed to each other in the direction orthogonal to the stacking direction and an area where they are arranged side by side in the stacking direction, there is no limitation thereto. The first node 21c and the second node 22c may be arranged side by side only in the stacking direction. In this case, a configuration may also be adopted in which the first node 21c is arranged on one surface of a single-layer double-sided substrate, and the second node 22c is arranged on the other surface thereof.

### Application to Vehicle

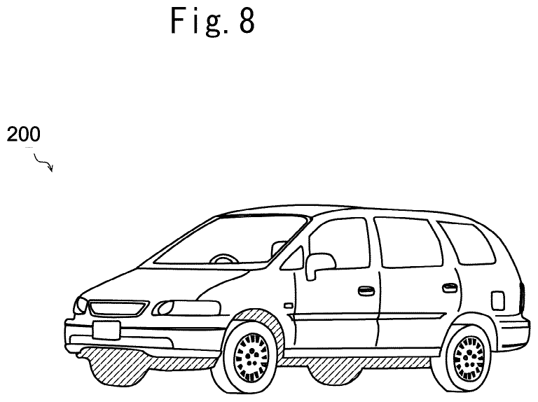

FIG. 8 is a view showing an outer appearance of a vehicle. In a vehicle 200 according to this configuration example, there are mounted various types of electronic apparatuses that operate upon receipt of electric power supplied from a battery.

Examples of the vehicle 200 include, in addition to an engine vehicle, an electric vehicle [an xEV such as a BEV [battery electric vehicle], a HEV [hybrid electric vehicle], a PHEV/PHV [plug-in hybrid electric vehicle/plug-in hybrid vehicle], or an FCEV/FCV [fuel cell electric vehicle/fuel cell vehicle]).

The semiconductor devices 100, 100A, 100B, and 100C described above can each be incorporated into a power supply device that supplies electric power to the electronic apparatuses mounted in the vehicle 200. Furthermore, they can also each be incorporated into any of the electronic apparatuses themselves. Moreover, they can also each be incorporated into an inverter device that controls a motor as a power source for an electric vehicle.

### Other Modifications

The foregoing embodiment is to be construed in all respects as illustrative and not limiting. The technical scope of the present disclosure is indicated by the appended claims rather than by the description of the foregoing embodiment, and it is to be understood that all changes that come within the meaning and range of equivalency of the claims are embraced therein.

### Clauses

The semiconductor device (100, 100A, 100B, 100C) described above is configured to include a pattern (2) formed therein. The pattern (2, 2A, 2B, 2C) includes a first node (21, 21a, 21b, 21c) formed in an outer circumferential portion in a planar view and configured to be connected to a first potential and a second node (22, 22b, 22c) arranged in an insulated state from the first node (21, 21a, 21b, 21c) and configured to receive application of a second potential different from the first potential. The first node (21, 21a, 21b, 21c) and the second node (22, 22b, 22c) are configured to be at least partly opposed to each other (a first configuration).

While there is an increasing demand for miniaturization of semiconductor devices, when an electronic component for EMS prevention is mounted in a semiconductor device, miniaturization of a package of the semiconductor device can hardly achieved. According to the first configuration, the first node and the second node of the pattern of the semiconductor device can be utilized to form a capacitor for EMI prevention, and thus compared with a configuration in which the electronic component is separately mounted, the semiconductor device can be simplified in configuration. As a result, miniaturization of the package of the semiconductor device can be achieved.

In the semiconductor device (100, 100A, 100B, 100C) according to the above-described first configuration, the second node (22, 22b, 22c) is configured to be positioned on an outer side relative to the first node (21, 21a, 21b, 21c) in the planar view (a second configuration).

In the semiconductor device (100C) according to the above-described first or second configuration, the pattern (2C) is formed of a plurality of layers stacked on each other, and the first node (21c) and the second node (22c) are formed on different ones of the plurality of layers and configured to include an area (21c2, 22c3) where they are opposed to each other in a stacking direction (a third configuration).

In the semiconductor device (100B) according to any of the above-described first to third configurations, the first node (21b) includes a plurality of first protrusions (211) configured to extend toward the second node (22b). The second node (22b) includes a plurality of second protrusions (221) configured to extend toward the first node (21b). The first protrusions (211) and the second protrusions (222) are arranged alternately and configured to include an area where each of the first protrusions (211) and an adjacent one of the second protrusions (222) are opposed to each other (a fourth configuration).

In the semiconductor device (100, 100A, 100B, 100C) according to any of the above-described first to fourth configurations, the first node (21, 21a, 21b, 21c) is configured to be connected to a ground potential (GND) (a fifth configuration).

In the semiconductor device (100, 100A, 100B, 100C) according to any of the above-described first to fifth configurations, the second node (22, 22b, 22c) is configured to be connected to a power supply potential (Ea) (a sixth configuration).

In the semiconductor device (100B) according to any of the above-described first to sixth configurations, the second node (24) is configured to be connected to an output potential (Eao) (a seventh configuration).

A power supply device (100, 100A, 100B, 100C) is configured to include the semiconductor device (100, 100A, 100B, 100C) according to any of the above-described first to seventh configurations (an eighth configuration).

An electric vehicle (200) is provided that is configured to include the power supply device (100, 100A, 100B, 100C) according to the above-described eighth configuration (a ninth configuration).

1. A semiconductor device, comprising:
a pattern formed therein,
wherein
the pattern includes:
a first node formed in an outer circumferential portion in a planar view and configured to be connected to a first potential; and
a second node arranged in an insulated state from the first node and configured to receive application of a second potential different from the first potential, and
the first node and the second node are configured to be at least partly opposed to each other.

2. The semiconductor device according to claim 1, wherein
the second node is configured to be positioned on an outer side relative to the first node in the planar view.

3. The semiconductor device according to claim 1, wherein
the pattern is formed of a plurality of layers stacked on each other, and
the first node and the second node are formed on different ones of the plurality of layers and configured to include an area where they are opposed to each other in a stacking direction.

4. The semiconductor device according to claim 1, wherein
the first node includes a plurality of first protrusions configured to extend toward the second node,
the second node includes a plurality of second protrusions configured to extend toward the first node, and
the first protrusions and the second protrusions are arranged alternately and configured to include an area where each of the first protrusions and an adjacent one of the second protrusions are opposed to each other.

5. The semiconductor device according to claim 1, wherein the first node is configured to be connected to a ground potential.

6. The semiconductor device according to claim 1, wherein
the second node is configured to be connected to a power supply potential.

7. The semiconductor device according to claim 1, wherein
the second node is configured to be connected to an output potential.

8. A power supply device, comprising:
the semiconductor device according to claim 1.

9. A vehicle, comprising:
the power supply device according to claim 8.
